(19) United States
(12) Patent Application Publication
(10) Pub. No.: US 2006/0197183 A1
(43) Pub. Date: Sep. 7, 2006

(54) IMPROVED MIM CAPACITOR STRUCTURE AND PROCESS

(75) Inventors: Chih-Chao Yang, Poughkeepsie, NY (US); Louis Hsu, Fishkill, NY (US); Haining Yang, Wappingers Falls, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/906,666

(22) Filed: Mar. 1, 2005

(51) Int. Cl. H01L 29/00; H01L 21/00

(52) U.S. Cl. 257/532; 438/396; 438/239; 257/535; 257/306

(57) ABSTRACT

An improved MIM capacitor structure and method where a selective plating process is used to form the capping layer on the copper capacitor electrodes. The metallic passivation layers prevent copper diffusion and enhance the reliability of the MIM capacitor.

### BACKGROUND OF THE INVENTION

The present invention relates, generally, to the field of semiconductor devices and more particularly to metal-insulator-metal (MIM) capacitors and a method for forming the capacitor structure.

Mixed signal and high frequency RF applications require high performance, high speed capacitors. Low series resistance, low loss and low RC time constants are required in these high frequency applications for high performance.

In semiconductor manufacturing processes, metal capacitors formed of metal-insulator-metal (MIM) are widely used in the design of semiconductor devices, particularly in high performance applications in CMOS technology. MIM capacitors have low resistance and low parasitic capacitance. MIM capacitors have superior high-frequency characteristics and more advantageous high speed properties. It is possible to further improve the high-frequency characteristics of the capacitor by the use of a copper material with a lower electrical resistance.

Also, as semiconductor devices become smaller capacitors are being formed over transistors at the metal level as opposed to being formed at the transistor level nearer the bulk semiconductor material. At the metal level, polysilicon cannot be used as an electrode material because deposition of polysilicon is a high temperature process that is not compatible with most BEOL high end processing. Since copper is replacing aluminum and aluminum alloys as the preferred material for metal interconnections it is desirable to use copper as the metal of a MIM capacitor electrode. However, there are problems associated with using copper with many high constant dielectric materials. These include poor mechanical and chemical stability of the copper interface with the capacitor dielectric materials. The use of copper leads to the diffusion of copper atoms into the dielectric between the electrodes of the capacitor and decreases the dielectric property and reliability of the capacitor.

Therefore, a need exists for a MIM capacitor structure which includes copper as a capacitor electrode with low resistance and which is compatible with conventional semiconductor processes and which alleviates the problems associated with copper electrodes.

Accordingly, Metal-Insulator-Metal (MIM) Capacitors have been integrated in various integrated circuits for applications of analog/logic, analog-to-digital, mixed signal, and radio frequency circuits. The conventional method of fabricating MIM capacitors is described with reference to FIGS. 1A-1G.

Referring to FIG. 1A, SiO₂ 102 and Si₃N₄ 103 are deposited in series on a wafer surface with interconnects 101 embedded in an insulator layer 100. Referring to FIG. 1B, the wafer is patterned with an alignment mask to create alignment marks at kerf area 120. Referring to FIGS. 1C and 1D, a first conductive TiN plate 104, a dielectric layer 105, a second conductive TiN plate 106, and a passivation Si₃N₄ layer 107 are sequentially deposited, and then patterned by a second masking and etching to obtain a top-electrode 130 of a capacitor.

Referring to FIGS. 1E and 1F, another Si₃N₄ layer is then deposited on the wafer, and then patterned by a third masking and etching to obtain a bottom-electrode 150 and insulator 140 of the capacitor. Referring to FIG. 1G, another insulator layer 109 is deposited on the wafer and then patterned to form electrical contacts 160 and 170.

This conventional method for integrating MIM capacitor structures into back-end-of-line (BEOL) semiconductor fabrication requires three additional masking and etching steps to form the capacitors and increases overall fabrication costs. Also, the capacitor-dielectric damage resulting from the top-electrode over-etch and the poor adhesion between Si₃N₄/Cu and Si₃N₄/TiN interfaces can cause reliability concerns. Further, the capacitor-dielectric thickness is required to be thicker than 500 Å in order to ensure an process window during top-electrode etch. This requirement limits the extendibility of the process to next technology generations. Also, the high resistivity electrode material, TiN, limits the Q (quality) factor of the MIM capacitor.

Therefore problems with current MIM capacitor processes include high cost, reliability concerns due to top plate over-etch causing dielectric damage around edge of the capacitor which leads to early TDDB (Time Dependent Dielectric Breakdown) fails, low Q Factor, high resistance of the TiN plates and scaling challenge related to the dielectric thickness.

There are a number of methods proposed by others for forming a MIM Capacitor Structure. Matsubayashi et al. U.S. Pat. No. 5,675,184 teaches a MIM Cap process in an RF (Radio Frequency) application. Thermoplastic material and magnetic substance layers are described.

Ma et al. U.S. Pat. No. 6,329,234 discloses a method of manufacturing a capacitor with a compatible copper process. However, the bottom plate is composed of copper and therefore has poor adhesion to the passivation Si₃N₄ layer, leading to a peeling phenomenon between the bottom electrode and the passivation layer.

Gambino et al. U.S. Pat. No. 5,879,985 teaches a capacitor using a damascene process for the lower electrode. Upper capacitor region has a crown type structure.

Loh et al. U.S. Pat. No. 6,670,237 teaches a method for simultaneously forming a MIM Cap and a dual damascene interconnects in a semiconductor device.

Kai et al. U.S. Pat. No. 6,461,914 teaches a MIM Cap which is aligned with damascene Cu interconnect plug, is created by a one-time etch of a stack of layers comprising Ta/capacitor-dielectric/Ta.

Lee et al. U.S. Pat. No. 6,764,915 teaches a MIM Cap structure having a Cu layer within a dielectric layer positioned on a substrate, an alloy layer atop the Cu layer, a metal oxide layer atop the alloy layer and a top pad layer atop the metal oxide layer.

Barth et al. U.S. Pat. No. 6,730,982 discloses a process of making an interconnection structure that does not rely on Al wirebond pads and can be integrated with a MIM capacitor.

Matsuhashi U.S. Pat. No. 6,759,703 discloses a MIM capacitor structure with a TaN/TiN barrier layer between a silicon nitride/oxide dielectric layer and Cu electrodes.

Notwithstanding the efforts of those skilled in the art, there remains a need for a MIM capacitor structure and process with improved reliability, high performance, better extendibility to thinner dielectrics and lower process cost.

Accordingly, it is an object of the present invention to provide a structure of a MIM capacitor without peeling and any reliability related concerns.

Another object of the present invention is to provide a method of forming the reliable MIM capacitor structure.

These and other objects of the invention will become more apparent after referring to the following description of the invention.

### BRIEF SUMMARY OF THE INVENTION

The objects of the invention have been achieved by providing a structure and corresponding methods for MIM capacitors in semiconductor devices. An aspect of the present invention provides a metal-insulator-metal (MIM) capacitor for a Cu BEOL semiconductor device comprising a bottom capacitor plate having a trench defined therein; a top capacitor plate disposed within said trench; a capacitor dielectric disposed between said capacitor plates within said trench; a first electrode electrically connected to said bottom plate; and a second electrode electrically connected to said top plate.

According to a preferred aspect, the inventive MIM capacitor further comprises a Cu diffusion barrier formed on said top and bottom plates. According to a more preferred aspect, the Cu diffusion barrier is selected from the group consisting of CoWP, CoSnP, Pd, Ru or other conductive materials.

According to another aspect of the present invention the bottom capacitor plate is a metal selected from the group consisting of copper, aluminum, or other electrical conductive materials.

Another aspect of the present inventive MIM capacitor comprises a capacitor dielectric disposed between two regions of metallization. According to an aspect, the capacitor dielectric is selected from the group consisting of oxide-nitride-oxide, SiO₂, TaO₅, PSiNₓSi₃N₄, SiON, SiC, TaO₂, ZrO₂, HfO₂, Al₂O₃, and combinations thereof. According to a preferred aspect, the capacitor dielectric preferably comprises high-k materials, e.g. TaO₅, TaO₂, ZrO₂, HfO₂.

According to another aspect the top plate of the inventive MIM capacitor is a metal selected from the group consisting of Cu, Ta, TaN, Ti, TiN, TiSiN, W, Ru, Al, alloys thereof, and mixtures thereof. According to a preferred aspect, the top capacitor plate preferably comprises of Cu.

According to another aspect the first and second electrodes of the inventive MIM capacitor are formed from a metal selected from the group consisting of Cu, Al, AlCu, Ti, TiN, Ta, TaN, W, WN, MoN, Pt, Pd, Os, Ru, IrO₂, ReO₂, ReO₃, alloys thereof and mixtures thereof. According to a preferred aspect, the first and second electrodes are formed of the same metal. According to a more preferred aspect, the electrodes are formed from Cu.

According to another aspect the present invention provides a method of fabricating a MIM capacitor for a Cu BEOL semiconductor device. According to an aspect the method comprises providing a semiconductor wafer; providing a first dielectric layer on said wafer; forming a first metallization in said dielectric, wherein an upper surface of said first metallization and an upper surface of said first dielectric form a substantially coplanar surface; forming a dielectric film on said coplanar surface; defining the MIM capacitor area through masking and etching, depositing the first passivation layer on top of exposed underneath interconnect surface, forming an intermetal dielectric layer over said first passivation layer; forming a second metallization over said intermetal dielectric; planarization to remove only the blanket capacitor dielectric material and the blanket conductive layer overlaying the substrate surface outside the capacitor area, selectively depositing the second passivation layer on top of said exposed second metallization surface; forming a layer of a second dielectric on said coplanar surface; forming a first electrode in said second dielectric in electrical contact with said first metallization; and forming a second electrode in said second dielectric in electrical contact with said second metallization.

According to a preferred aspect, the inventive method of fabricating an MIM capacitor further comprises forming a Cu diffusion barrier on said first and second metallization layers. According to a more preferred aspect, the Cu diffusion barrier is selected from the group consisting of CoWP, CoSnP, Pd, Ru or other conductive materials.

According to another aspect, the present invention provides an MIM capacitor fabricated according to the inventive method. Still other aspects and advantages of the present invention will become readily apparent by those skilled in the art from the following detailed description, wherein it is shown and described preferred embodiments of the invention, simply by way of illustration of the best mode contemplated of carrying out the invention. As will be realized the invention is capable of other and different embodiments, and its several details are capable of modifications in various obvious respects, without departing from the invention. Accordingly, the description is to be regarded as illustrative in nature and not as restrictive.

### BRIEF DESCRIPTION OF THE DRAWINGS

The features of the invention believed to be novel and the elements characteristic of the invention are set forth with particularity in the appended claims. The Figures are for illustration purposes only and are not drawn to scale. The invention itself, however, both as to organization and method of operation, may best be understood by reference to the detailed description which follows taken in conjunction with the accompanying drawings in which:

FIGS. 1A-1G are a schematic representation of a conventional MIM capacitor fabrication method.

FIGS. 2-8 are a schematic representation of a MIM capacitor fabrication method according to the present invention.

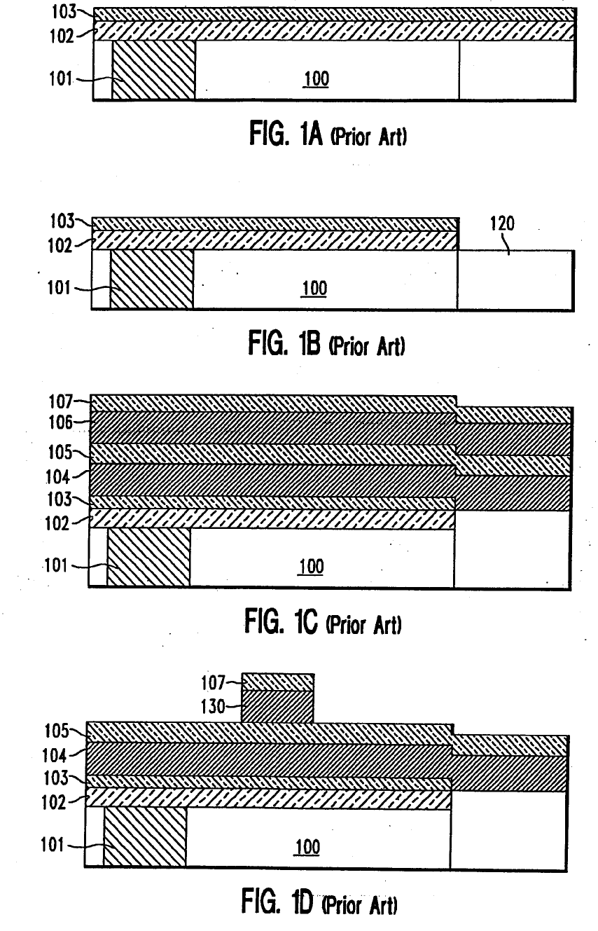

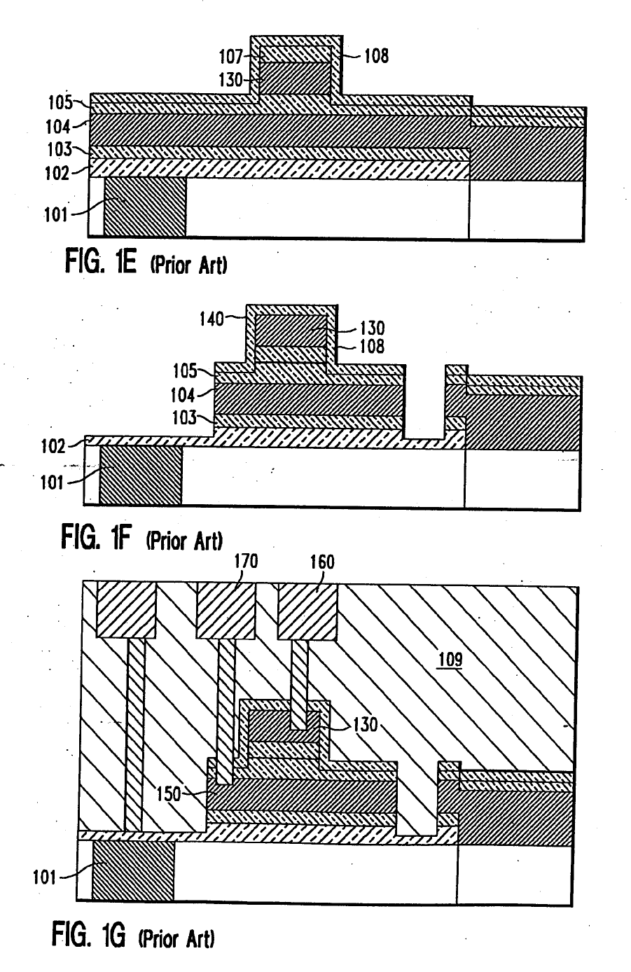

### DETAILED DESCRIPTION OF THE INVENTION

According to the claimed invention, the MIM capacitor structure comprises two copper electrodes and two metallic passivation layers. Preferred materials for the metallic passivation layers include CoWP, CoSnP, Pd and Ru. Both the top and bottom copper electrodes are capped with the passivation layers. One advantage of the present invention is that a selective plating process is performed to form the capping layer on the copper electrodes. The peeling phenomenon and or electro migration failure occurring between the dielectric/metal interface is thereby prevented. In addition, the passivation layers are employed as copper diffusion barrier layers. The diffusion of metallic electrode ions into the surrounding dielectrics is prevented. These features enhance the reliability of the MIM capacitor.

Other advantages of the present invention include high performance by adopting Cu electrodes, better technology extendibility through scalable dielectric thickness and low cost of the present proposed integration process.

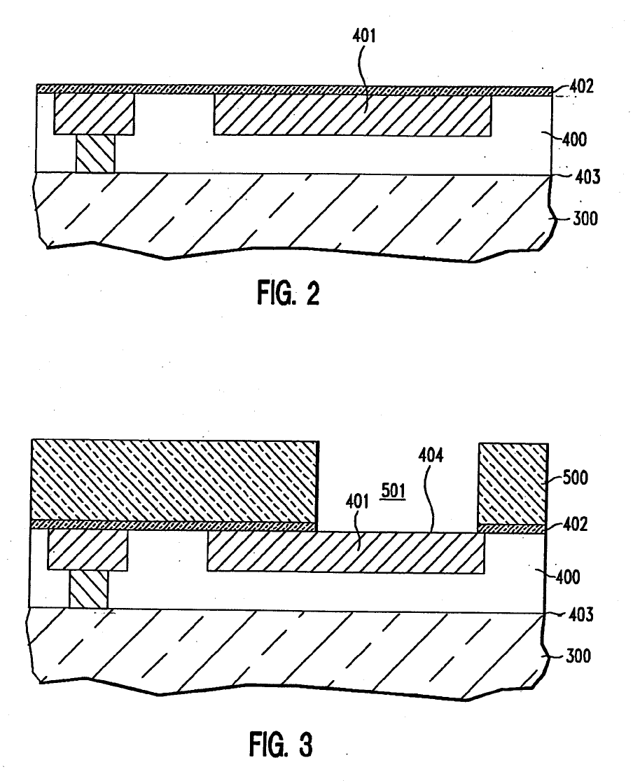

Referring to the Figures in more detail, and particularly referring to FIG. 2, there is shown a substrate 300 having a first dielectric layer 402 which is deposited on the substrate surface 403 with conductive interconnects 401 embedded in a first insulator layer 400. The first dielectric layer 402 may be, for example, SiN, SiC, SiO, SiLK or other low-k dielectric materials. In a preferred embodiment the conductive interconnects 401 are copper.

Referring now to FIG. 3, a second dielectric layer 500 is deposited on the substrate and then patterned by masking and etching to define the area of a capacitor 501. The underlying conductive interconnect 401 is exposed and this exposed area will be used to form the bottom electrode of the capacitor 404. In a preferred embodiment the capacitor bottom electrode 404 is copper. In a preferred embodiment the second dielectric layer 500 is composed of oxide and has a thickness between about 500 and 10,000 Å.

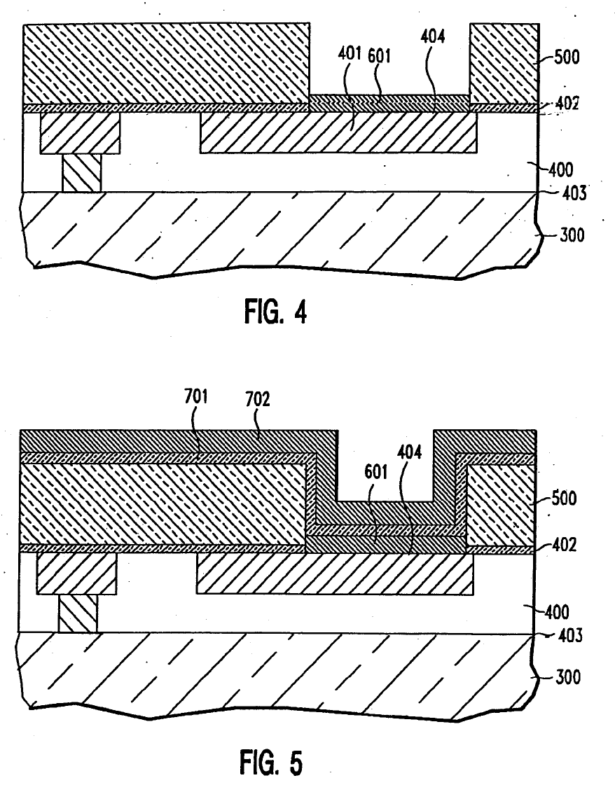

Referring now to FIG. 4, a first conductive capacitor layer 601 is selectively plated on top of the bottom electrode of the capacitor 404. The first conductive capacitor layer 601 will function as both a passivation layer and a diffusion barrier. In a preferred embodiment the first conductive capacitor layer 601 is a CoWP layer with a thickness of approximately 50 to 300 Å. Other preferred materials, for example, CoSnP, Pd, and Ru can also be used as the first conductive layer 601.

Referring now to FIG. 5, a blanket capacitor dielectric material 701 and a blanket conductive layer 702 are deposited sequentially on top of the substrate. In a preferred embodiment the capacitor dielectric material 701 is a high dielectric constant material. In a preferred embodiment the blanket conductive layer 702 is copper. In a preferred embodiment the capacitor dielectric material 701 is a high dielectric constant material, for example, oxide-nitride-oxide, SiO₂, TaO₅, PSiNₓ, Si₃N₄, SiON, SiC, TaO₂, ZrO₂, HfO₂ or Al₂O₃. The deposition methods can be, for example, Plasma Vapor Deposition (PVD), Chemical Vapor Deposition (CVD), electroplating, electroless plating, or spin-on processes. In a preferred embodiment the capacitor dielectric 701 thickness is approximately 50 to 1,000 Å, and the thickness of the blanket conductive layer 702 is between approximately 200 and 1,000 Å.

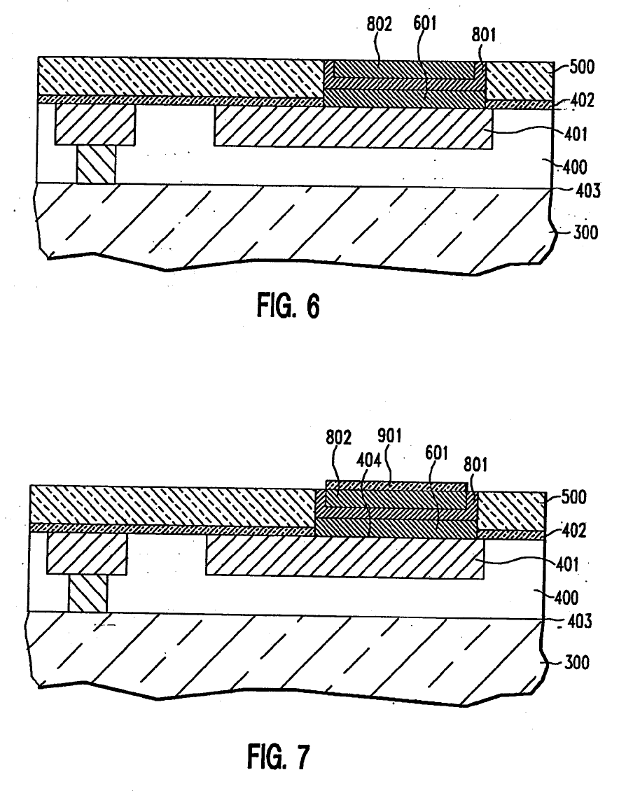

Referring now to FIG. 6, a conventional planarization process, such as an etch back process or a Chemical Mechanical Polishing (CMP) process is used to remove only the blanket capacitor dielectric material 701 and the blanket conductive layer 702 overlaying the substrate surface 403 outside the capacitor area 501 and thereby form the capacitor dielectric 801 and the top capacitor electrode 802. In a preferred embodiment the top capacitor electrode 802 is copper.

Referring now to FIG. 7, a second conductive capacitor layer 901 is selectively plated on top of the top capacitor electrode 802 and used as both a passivation layer and a diffusion barrier. In a preferred embodiment the second conductive capacitor layer 901 is CoWP. The second conductive capacitor layer 901 thickness is preferably between approximately 50 and 300 Å. Other preferred materials, for example, CoSnP, Pd, and Ru can also be used as the second conductive layer 901.

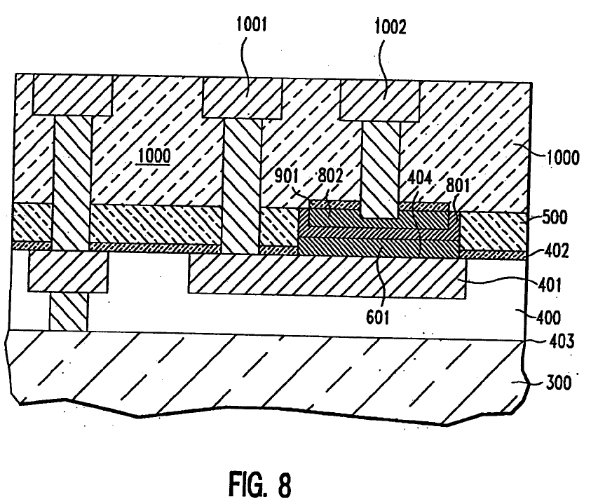

Referring now to FIG. 8, a second insulating layer 1000 is deposited on the substrate, and then patterned to form a first electrical interconnect 1001 and a second electrical interconnect 1002. The top capacitor electrode 802, the capacitor dielectric 801, and the bottom capacitor electrode 404 form a MIM capacitor. In a preferred embodiment the top capacitor electrode 802 and the bottom capacitor electrode 404 are copper. The second electrical interconnect 1002, also referred to as a capacitor top plate trench plug, contacts the top capacitor electrode 802. The first electrical interconnect 1001, also referred to as a capacitor bottom plate trench plug contacts the bottom capacitor electrode 404. In a preferred embodiment the first electrical interconnect 1001 and the second electrical interconnect 1002 are copper. In a preferred embodiment the dielectric layer 1000 is composed of low-k dielectrics, for example, SiN, SiC, SiO, SiLK, or other low-k dielectric materials, and has a thickness between approximately 500 and 10,000 Å.

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

What is claimed is:

1. A semiconductor device comprising:
a substrate;
a first insulator layer atop said substrate;
a capacitor bottom electrode embedded in said first insulator layer;
a first conductive capacitor layer atop said capacitor bottom electrode;
a capacitor dielectric layer atop said first conductive layer;
a capacitor top electrode atop said capacitor dielectric layer; and
a second conductive capacitor layer atop said capacitor top electrode.

2. The semiconductor device of claim 1 further comprising:
a first electrical interconnect in electrical contact with said capacitor bottom electrode;
a second electrical interconnect in electrical contact with said capacitor top electrode; and
a dielectric material at least partially embedding said first and second electrical interconnects.

3. The semiconductor device of claim 1, wherein said capacitor bottom electrode and said capacitor top electrode are comprised of copper.

4. The semiconductor device of claim 1, wherein said first conductive layer and said second conductive layer are selected from the group consisting of CoWP, CoSnP, Pd, and Ru.

5. The semiconductor device of claim 4, wherein said first conductive layer and said second conductive layer have a thickness of approximately 50 to 300 Å.

6. The semiconductor device of claim 1, wherein said capacitor dielectric layer is a high dielectric constant material selected from the group consisting of oxide-nitride-oxide, SiO₂, TaO₅, PSiNₓ, Si₃N₄, SiON, SiC, TaO₂, ZrO₂, HfO₂ and Al₂O₃.

7. The semiconductor device of claim 1, wherein said capacitor dielectric layer has a thickness of approximately 50 to 1,000 Å.

8. The semiconductor device of claim 3, wherein said capacitor top electrode has a thickness of approximately 200 to 1,000 Å.

9. The semiconductor device of claim 2, wherein said first electrical interconnect and said second electrical interconnect are comprised of copper.

10. The semiconductor device of claim 1, wherein said capacitor bottom electrode and said capacitor top electrode are a material selected from the group consisting of Al, AlCu, Ti, TiN, Ta, TaN, W, WN, MoN, Pt, Pd, Os, Ru, IrO₂, ReO₂ and ReO₃.

11. A method of fabricating a semiconductor device, the method comprising the steps of:
providing a substrate;
forming a conductive interconnect embedded in a first insulator layer atop said substrate;
forming a first dielectric layer atop said conductive interconnect and said first insulator layer;
forming a second dielectric layer atop said first dielectric layer and forming a recessed opening through said first and second dielectric layers to expose at least a portion of said conductive interconnect and thereby forming a capacitor bottom electrode;
forming a first conductive layer atop said capacitor bottom electrode;
forming a blanket capacitor dielectric layer atop said second dielectric layer and said first conductive layer;
forming a blanket conductive layer atop said blanket capacitor dielectric material;
planarizing said blanket conductive layer and said blanket capacitor dielectric layer to expose said second dielectric layer and thereby forming a capacitor dielectric layer atop said first conductive layer and a capacitor top electrode atop said capacitor dielectric layer; and
forming a second conductive layer atop said capacitor top electrode.

12. The method of claim 11 further comprising the steps of:
forming a second insulating layer atop said second dielectric layer and said second conductive layer;
patterning said second insulating layer to form a first recessed opening exposing at least a portion of said conductive interconnect and a second recessed opening exposing at least a portion of said second conductive layer; and
depositing a conductive material in said first and second recessed openings thereby forming a first electrical interconnect to said capacitor bottom electrode and a second electrical interconnect to said top capacitor electrode.

13. The method of claim 11, wherein said first dielectric layer is selected from the group consisting of SiN, SiC, SiO and SiLK.

14. The method of claim 11, wherein said conductive interconnect is comprised of copper.

15. The method of claim 11, wherein said capacitor bottom electrode and said capacitor top electrode are comprised of copper.

16. The method of claim 11, wherein said second dielectric layer has a thickness of approximately 500 to 10,000 Å.

17. The method of claim 11, wherein said first conductive layer and said second conductive layer are selected from the group consisting of CoWP, CoSnP, Pd and Ru.

18. The method of claim 17, wherein said first conductive layer and said second conductive layer have a thickness of approximately 50 to 300 Å.

19. The method of claim 11, wherein said blanket capacitor dielectric layer is comprised of a high dielectric constant material selected from the group consisting of oxide-nitride-oxide, SiO₂, TaO₅, PSiNₓ, Si₃N₄, SiON, SiC, TaO₂, ZrO₂, HfO₂ and Al₂O₃.

20. The method of claim 11, wherein said capacitor dielectric layer has a thickness of approximately 50 to 1,000 Å.

21. The method of claim 14, wherein said capacitor top electrode has a thickness of approximately 200 to 1,000 Å.

22. The method of claim 12, wherein said first electrical interconnect and said second electrical interconnect are comprised of copper.

23. The method of claim 11, wherein said capacitor bottom electrode and said capacitor top electrode are a material selected from the group consisting of Al, AlCu, Ti, TiN, Ta, TaN, W, WN, MoN, Pt, Pd, Os, Ru, IrO₂, ReO₂ and ReO₃.

24. The method of claim 17, wherein said first conductive layer and said second conductive layer are selectively plated.
